(19) United States
(12) Patent Application Publication
(10) Pub. No.: US 2011/0259419 A1
(43) Pub. Date: Oct. 27, 2011

(54) SOLAR CELL WITH AN IMPROVED PIGMENTED DIELECTRIC REFLECTOR

(76) Inventors: Volker Hagemann, Klein-Winternheim (DE); Matthias Bockmeyer, Mainz (DE); Peter Lechner, Vaterstetten (DE); Michael Berginski, Essen (DE)

(21) Appl. No.: 12/891,024

(22) Filed: Sep. 27, 2010

(30) Foreign Application Priority Data
Sep. 28, 2009 (DE) 10 2009 043 047.4

(51) Int. Cl. H01L 31/0232; H01L 31/0368

(52) U.S. Cl. 136/259; 136/258

(57) ABSTRACT

The solar cell has a pigmented dielectric reflector, which includes two dielectric layers with different refractive indices and pigments embedded in the layers, so that the solar cell has good light-trapping properties and high efficiency with a small reflector layer thickness. The material systems suitable for producing the pigmented dielectric reflector are also part of the invention.

### CROSS-REFERENCE

The subject matter described and claimed herein below is also described in German Patent Application No. 10 2009 043 047.4, filed on Sep. 28, 2009, in Germany. This German Patent Application provides the basis for a claim of priority of invention for the invention described and claimed herein below under 35 U.S.C. 119 (a)-(d).

### BACKGROUND OF THE INVENTION

### The Field of the Invention

The present invention relates to a solar cell having a dielectric pigmented reflector.

Solar cells of various designs generally have a back reflector, which increases the optical path of the radiation through the photovoltaic cells so that the absorption and therefore the efficiency of the solar cell are improved.

On the one hand metallic reflectors made for example of Al or Ag are known from the prior art, which produce directional metallic reflection of the incident radiation. When the solar cell is oriented perpendicularly to the main radiation source and the reflector layer is planar, the optical path through the photovoltaic absorber can thus approximately be doubled. Furthermore the optical reflector may have a microstructured rough surface, so that some of the radiation is reflected obliquely with respect to the light incidence axis and therefore has a longer path through the absorber.

The prior art also discloses pigmented dielectric reflectors which, unlike metallic reflectors, exhibit diffuse, non-directional reflection and which scatter the incident radiation in a wide angular range. In the ideal case, the incident radiation is scattered back by a planar reflector made of a dielectric material with a Lambertian scattering characteristic, i.e. with a constant ray density in the half-space. The angular distribution of the back-scattered radiation, which is also referred to as the scattering lobe, in this case has a width of 180°, with the radiation density following the Lambert cosine law. The diffusely reflected radiation can generally be absorbed more efficiently on a smooth semiconductor surface than in the case of a metallic reflector, since the optical path of the radiation through the absorber is more than doubled with radiation which is oblique with respect to the incidence direction. Furthermore total reflection can occur for obliquely reflected light, for example at the interface of the absorber layer with the electrode layer, so that the remaining radiation again passes through the absorber. The resulting light path of the radiation through the absorber can therefore even be much greater than double the absorber layer thickness. This effect is also referred to as light trapping. A dielectric reflector may in principle also be used on rough surfaces, in which case effects of interfacial scattering and bulk scattering from the dielectric reflector will be superimposed.

In the case of a dielectric reflector, between the photovoltaic layer and the electrically nonconductive reflector, there is generally a transparent conductive oxide layer (abbreviated to TCO), via which the current is discharged, since in contrast to a metallic reflector the back reflector is not suitable as a back electrode owing to its lack of electrical conductivity. The dielectric reflector accordingly then rests on this TCO layer, so that the reflected radiation must pass through the TCO layer again before it re-enters the photovoltaic absorber. By heavy doping of the semiconductor layers, however, the conductivity of the photovoltaic layer may also be increased to such an extent that it can itself discharge the photocurrent. In this case, the dielectric back reflector rests directly on the semiconductor layer.

WO 2005/076370 A2, for example, describes the use of a dielectric reflector in the form of a white medium, which consists of a carrier material containing pigments, the ratio of the refractive index n of the pigments to the refractive index of the carrier material lying in the range of from 1.4 to 2, and the proportion of pigments in the white medium being from 10 to 100 vol %. Particles, for example of BaSO₄ or TiO₂, with a particle size of from 0.2 μm to 2 μm are mentioned as pigments. As carrier substances for the pigments, organic carrier materials such as EVA (ethyl-vinyl-acetate) and the carrier substances of commercially available paints are mentioned. The dielectric reflector can be applied either in the form of a white paint or in the form of a film which contains the pigments. A disadvantage of the described carrier substances, however, is that the refractive index of the carrier substance is low, which applies both for EVA film and for the commercially available white paints, since the strong difference between the refractive indexes of the dielectric reflector and the semiconductor layer entails strong refraction of the radiation according to Snell's law of refraction. The width of the angular distribution of the back-scattered light is therefore reduced to a much smaller aperture angle when entering the Si with a high refractive index of n≈3.7, so that the solar cell cannot develop the optimal light-trapping potential.

For the case of direct paint application onto silicon, the article “Novel light-trapping schemes involving planar junctions and diffuse rear reflectors for thin-film silicon-based solar cells”, K. Winz et al., Solar Energy Materials and Solar Cells 49 (1997), 195-203, proposes the use of a paint having a high refractive index of the carrier substance. The refraction at the interface with the Si absorber is thereby reduced, so that the aperture angle of the scattering lobe in the Si absorber is increased and the light trapping is improved. A disadvantage of this solution is that increasing the refractive index of the carrier substance by using the same pigments reduces the coverage capacity of the paint, and the paint layer must correspondingly be thicker in order to achieve sufficient coverage.

### SUMMARY OF THE INVENTION

It is therefore an object of the invention to provide a solar cell having a dielectric reflector with a high reflectivity, which in comparison with the prior art has both a small layer thickness and as wide as possible a scattering lobe of the radiation scattered back into the absorber, and therefore good light-trapping properties and a high efficiency.

The object is attained by the solar cell described in the main independent claim appended herein below. Preferred embodiments are described in the dependent claims.

According to the invention the solar cell comprises a plurality of functional layers, which include a front electrode layer, a photovoltaically active absorber layer, a back electrode layer and a pigmented dielectric reflector.

The solar cell may be either a crystalline solar cell based on a semiconductor wafer or a thin-film solar cell having a substrate or superstrate arrangement. In the case of a superstrate arrangement, the incident radiation travels through the substrate into the absorber layer. The solar cell may also include other elements, for example for contacting and for backside encapsulation, which are not essential to the subject-matter of the invention.

The front electrode layer may, for example, comprise a TCO layer of SnO₂, ITO (indium tin oxide) or ZnO, ZnO preferably doped with Al, Ga or B and SnO₂ and/or ITO, preferably doped with F. The front electrode layer may, however, also be in the form of a semiconductor layer in conjunction with an unclosed metal layer, for example using interconnects printed onto the semiconductor. The electrical conductivity of the semiconductor layer may in this case be increased by heavy doping.

The photovoltaically active absorber layer, in which the conversion of the optical energy into electrical energy takes place, may be based on the semiconductor material Si in amorphous or crystalline form, although it may also comprise other material systems, such as CdTe or CIGS (Cu(ln, Ga) (S, Se)₂). The photovoltaically active absorber layer may comprise one or more p-n junctions, and may for example comprise single or multiple stacked cells (in particular tandem or triple junction stacked cells) consisting of amorphous and/or monocrystalline semiconductor material.

The back electrode layer may likewise comprise a TCO layer of SnO₂, ITO or ZnO, ZnO preferably doped with Al, Ga or B and SnO₂ and/or ITO, preferably doped with F. The back electrode layer may, however, also be part of the absorber layer. By near-surface doping of the generally semiconducting absorber layer, its conductivity can be increased there to such an extent that the current is discharged via the absorber layer.

The pigmented dielectric reflector is generally distinguished in that it comprises an electrically nonconductive carrier substance, in which pigments that cause light scattering are embedded. It is distinguished by diffuse reflection and, because of its spectral reflection properties, is generally white.

In the present disclosure, the term “refractive index” refers to the value of the refractive index at a wavelength of approximately 800 nm. The shorter-wavelength solar radiation is, as a rule, generally already absorbed during the first transit of the radiation through the photovoltaic absorber layer, so that it does not reach the dielectric reflector. The corresponding short wavelength range comprises, depending on the absorber material and the layer thickness, a range of 300 nm to 500 nm or 300 nm to 600 nm. The dielectric reflector therefore primarily reflects radiation in the wavelength range above 500 nm to 600 nm, the wavelength of 800 nm being regarded as representative of this range. The change in the refractive index with the wavelength can be neglected in the present disclosure, since it is small compared with the refractive index differences of the individual layers within the layer system.

The solar cell according to the invention is characterized by a pigmented dielectric reflector having a refractive index profile perpendicular to the functional layers with at least two different refractive indexes, wherein the refractive index profile includes a refractive index n₁ at a distance d₁ from the absorber layer and a refractive index n₂ at a distance d₂ from the absorber layer, wherein the distance d₂ is greater than the distance d₁ and the refractive index n₁ closer to the absorber layer is greater than the refractive index n₂ further from the absorber layer. The refractive index of the pigmented dielectric reflector used in the physical model is in this case taken to be the refractive index of the carrier substance without taking the pigments into account.

The invention is explained further herein below by means of an example for the case in which the refractive index profile of the pigmented dielectric reflector has two different refractive indexes. In this case, which is illustrated in FIG. 2 herein below, the dielectric reflector has a two-layer structure with a high-index first reflector layer and a low-index second reflector layer. The high refractive index of the side of the dielectric reflector closest to the absorber layer advantageously leads to the width of the angular distribution of the radiation scattered back into the absorber layer not being reduced as strongly when it enters the absorber layer as is the case with a low-index reflector layer. For example, a scattering lobe with a maximum possible angular distribution width of 180° in a low-index layer with a refractive index of n=1.5 is reduced in a high-index absorber layer with a refractive index of n≈4 to an angular distribution width of only about 44°. This latter case is illustrated in FIG. 1. When entering a high-index absorber layer with a refractive index of n≈4 from a high-index layer with a refractive index of n=1.8, the angular distribution width in the high-index absorber layer is reduced to a value still equal to 53°. Because of the greater scattering angles, the optical path of the reflected radiation in the absorber layer is lengthened and the light-trapping properties of the solar cell are improved.

If the same pigment is used in the high-index and low-index reflector layers, then the carrier substance of the high-index reflector layer generally has a lower coverage capacity, since the coverage capacity depends on the refractive index difference between the pigments and the carrier substance. To a first approximation, it may be assumed that the coverage capacity of a reflector layer having a carrier substance with a refractive index n_{T} and pigments with a refractive index n_{P} is proportional to the expression (n_{P}−n_{T})²/(n_{P}+n_{T})². For a pigment refractive index of 2.5, this gives a coverage capacity which is less by a factor of 2.3 when the refractive index of the carrier substance is increased from 1.5 to 1.8. Correspondingly, in this example, the high-index reflector must have a layer thickness which is greater by a factor of 2.3 than that of the low-index reflector, so that the same opacity is achieved. A high-index reflector must therefore have a much greater layer thickness, if it is intended to have a sufficiently high opacity or a sufficiently low translucence of approximately 0%.

According to the invention, however, the high-index reflector layer is supplemented with a low-index second reflector layer which, because a lower refractive index of the carrier substance has a higher coverage capacity so that a sufficient opacity is already achieved with small layer thicknesses. The radiation which is scattered back by this low-index layer in the direction of the absorber layer then again passes through the high-index reflector layer and can still be scattered into the widened scattering lobe by further scattering. At the transition between the low-index and high-index reflector layers, refraction also takes place which leads to a reduction in the width of the angular distribution. The radiation reflected by the low-index layer can nevertheless be scattered again into the range of the widened scattering lobe by further scattering processes inside the high-index layer, so that effective broadening of the scattering lobe is achieved overall, i.e. an increase in the width of the angular distribution.

The functional principle of a two-layer reflector, as explained, may alternatively also be implemented using a multilayer dielectric reflector having three or more reflector layers with a stepped refractive index profile or using a reflector layer having a refractive index which increases continuously in the direction of the absorber layer. The refractive index profile may also increase incrementally with an increasing distance from the absorber, which reduces the occurrence of the advantages according to the invention but still allows the advantages of the invention to be achieved with a corresponding configuration of the refractive index profile (small layer thickness, small refractive index difference). In general, the structure of the solar cell according to the invention can therefore be described in that the pigmented dielectric reflector has a refractive index profile perpendicular to the functional layers with at least two different refractive indexes n₁ and n₂, which has a refractive index n₁ at a distance d₁ from the absorber layer or absorber and a refractive index n₂ at a distance d₂ from the absorber layer or the absorber, wherein the distance d₂ is greater than the distance d₁ and the refractive index n₁ closer to the absorber is greater than the refractive index n₂ further from the absorber.

Preferred embodiments of the invention are set forth herein below. In a first preferred embodiment, the back electrode layer is formed by a TCO layer having a refractive index n_{R}, the maximum refractive index of the dielectric layer corresponding at most to the refractive index n_{R} of the TCO layer. This situation leads to the layer sequence reflector-TCO-absorber, which corresponds to the standard structure, for example of thin-film solar cells having a dielectric reflector. A TCO layer generally has a refractive index which lies between that of the dielectric reflector (in the prior art: n≈1.5) and that of the absorber (for Si: n≈3.7). The TCO material ZnO which is often used has, for example, a refractive index of approximately 1.8. In the case of an additional TCO layer, refractions take place at two interfaces, the reflector-TCO interface and TCO-absorber interface, which correspond in their effect to refraction between the reflector and absorber. In the case of an additional TCO layer between the back electrode and the absorber, the refractive index of the high-index reflector layer should, however, be selected to be at most as high as the refractive index of the TCO layer, since the TCO layer limits the width of the angular distribution of the reflected radiation within the absorber layer to a maximum value of 53° and a further increase in the refractive index of the first reflector layer above the refractive index of the TCO layer would not lead to any further widening of the angular distribution.

In another embodiment, the back electrode layer is formed by a heavily doped surface layer of the absorber layer. This situation leads to the layer structure reflector-absorber, which corresponds to the standard structure of a commercially produced type of solar cell. In this case, a refractive index of the dielectric reflector reaching the level of the refractive index of the absorber layer in principle has a positive effect on the width of the scattering lobe in the absorber layer. In practice, however, available pigments and carrier substances also entail limitations here for the refractive index of the reflector layer.

According to the invention, the pigmented dielectric reflector has a refractive index profile with at least two different refractive indexes n₁ and n₂ perpendicularly to the functional layers, with a refractive index n₁ at a distance d₁ from the absorber and a refractive index n₂ at a distance d₂ from the absorber, the refractive index n₁ close to the absorber being greater than the refractive index n₂ further from the absorber. The refractive index profile may in this case correspond to a stepped profile and increase in a plurality of individual steps in the direction of the absorber layer, although it may also be a continuous refractive index profile. In a less preferred embodiment the refractive index of the pigmented dielectric reflector increases continuously in the direction of the absorber layer. A continuous profile of the refractive index over the thickness of the reflector may, for example, be produced by continuously varying the layer composition of the reflector during its deposition process. Preferably, however, the pigmented dielectric reflector comprises a plurality of individual layers, each with a constant composition and constant refractive index within an individual layer.

In a preferred embodiment, the pigmented dielectric reflector comprises a first reflector layer facing towards the absorber layer and a second reflector layer, the first reflector layer comprising a first carrier substance with a refractive index n_{T,1} and pigments embedded therein, and the second reflector layer comprising a second carrier substance with a refractive index n_{T,2} and pigments embedded therein. This embodiment can generally be produced with the least outlay on fabrication technology, and is therefore preferred.

The reflector layers are formed by pigments within a carrier substance. The pigments preferably comprise at least one pigment from the group consisting of rutile, anatase, BaSO₄ or ZnS and have a particle size in the range of from 0.1 μm to 5 μm, preferably in the range of from 0.1 μm to 1 μm. The said white pigments are distinguished by high refractive indexes and high spectral reflection in the visible spectral range and in the NIR (near infrared). The best scattering effect is furthermore achieved when the particles have specific particle sizes in the range of the wavelengths of the radiation to be scattered. With even smaller particles, the scattering effect increases significantly. Much larger particles exhibit strong scattering on their surface, but the total surface area per unit volume is reduced in the case of the larger particles. Particularly preferably, therefore, the pigments have a particle size in the range of from 0.1 μm to 1 μm.

The proportion of the pigments in the first and second reflector layers is preferably from 10 vol % to 90 vol % and preferably from 30 vol % to 60 vol %. The greatest scattering effect is generally achieved with these pigment proportions, since the proportion of scattering interfaces per unit volume is then particularly high and the greatest coverage capacity is therefore achieved. The layer thicknesses of the reflector layers can accordingly have a small layer thickness.

In another embodiment, the first reflector layer has a translucence of 10% to 90%, preferably from 25% to 75%. In this preferred medium translucence range of 25% to 75%, the advantages according to the invention are achieved to the greatest extent, since then on the one hand the first reflector layer can have a relatively small layer thickness and a small overall layer thickness of the reflector can be achieved, and on the other hand the radiation scattered back by a further reflector layer is scattered within the first reflector layer into a larger angular range again with a correspondingly high probability. With a translucence of less than 10% or more than 90%, however, this is the case only to a limited extent.

In a preferred embodiment, the carrier substance of the first reflector layer has a refractive index n_{T,1} of at least 1.6, preferably at least 1.7 and particularly preferably at least 1.8.

In another preferred embodiment, the carrier substance of the second reflector layer has a refractive index n_{T,2} of less than 1.6, preferably less than 1.55 and particularly preferably less than 1.5. The refractive indexes of the reflector layers are contingent in particular on the availability of suitable carrier substances and pigments having the desired physical properties, which in conjunction with the required refractive index difference between the reflector layers allows an optimal reflector structure. The carrier substance in the low-index second reflector layer may in principle have a very low refractive index in the range of from 1.0 to 1.5, although it is limited by available suitable materials to a range of from about 1.3 to about 1.6. The lower that the refractive index is, the greater is the coverage for an equal pigment refractive index, and the lower is the translucence for a given layer thickness.

The refractive index n_{T,1} is preferably at least 0.1, preferably at least 0.2 and particularly preferably at least 0.3 greater than the refractive index n_{T,2}, the advantages according to the invention becoming more and more pronounced with an increasing refractive index difference. Yet since the carrier substance is intended to have a transmission which is as high as possible, and must have other properties, no carrier substances with a refractive index>1.6 are to be found among those commercially available. Besides the requirement for the refractive index, the carrier substances must also be distinguished by good weathering resistance, good mechanical strength and thermal cycle stability.

The corresponding refractive indexes of the carrier substances, and the refractive index difference between the first and second reflector layers, may be achieved using various materials systems. According to the invention the first reflector layer must have a high refractive index, which cannot readily be achieved using carrier substances of commercially available paints.

The carrier substance of the first reflector layer preferably comprises an organic and/or hybrid polymeric and/or polysiloxane-based base material, and particularly preferably an organic/inorganic hybrid polymer as the base material, and may furthermore comprise high-index nanoparticles.

The carrier substance of the first reflector layer is preferably produced according to the sol-gel method from hydrolyzable and polycondensable silicon or silicon-organic compounds and optionally hydrolyzable and poiycondensable titanium, zirconium, aluminium, zinc, magnesium, calcium, cerium, samarium, gadolinium, lanthanum, boron, yttrium and/or tin compounds. For example, these condensable components may be selected from the group consisting of acrylsilanes, epoxysilanes, acrylalkoxysilanes, acrylepoxysilanes, epoxyalkoxysilanes, allylsilanes, vinylsilanes, fluoralkylsilanes, aminosilanes, alkoxysilanes, metal alcoholates, metal oxide acrylates, metal oxide methacrylates and metal oxide acetylacetonates. In particular, they are for example the following substances: methacryloxypropylsilane, glycidylpropylsilane, zirconium secondary butyl acrylate, titanium ethyl acrylate, titanium propyl acrylate, zirconium secondary butyl methacrylate, titanium ethyl methacrylate, titanium propyl methacrylate, tetraethoxysilane, tetramethoxysilane, methyltriethoxysilane, methyltrimethoxysilane, ethyltrimethoxysilane, propyltrimethoxysilane, mercaptopropyltrimethoxysilane, aminopropylsilane, vinyltriethoxysilane, allyltriethoxysilane, phenyltriethoxysilane, triethoxysilylpropylsuccinic anhydride, fluorooctylsilane. The condensate is characterized in that the inorganic condensation degree of the hydrolyzate is greater than or equal to 50%, preferably greater than 70%.

Preferably, the silicon or silicon-organic compound is photochemically or thermally polymerizable.

Besides the said base material, the first carrier substance of the first reflector layer may also comprise high-index nanoparticles with a refractive index of at least 2.0 in a proportion of at least 10 vol %, preferably at least 20 vol % having an average size of from 2 nm to 50 nm, preferably from 4 nm to 30 nm, so that the refractive index is increased. In contrast to larger pigments, because of their small size below the wavelength of solar radiation, nanoparticles cause only very minor scattering of the radiation but essentially lead to a refractive index increase of the carrier substance. Because of this different physical effect, in contrast to the pigments, the nanoparticles in the present invention may be regarded as a component of the carrier substance, and are correspondingly prepared as such. The nanoparticles are preferably used in particular due to their high refractive index, but also owing to good availability. A high refractive index from 1.6 to 2.1, preferably from 1.65 to 1.85, can be achieved in this way.

The high-index nanoparticles preferably comprise one or more oxides from the group consisting of ZrO₂, Y₂O₃ stabilized ZrO₂, CaO-stabilized ZrO₂, MgO-stabilized ZrO₂, CeO₂-stabilized ZrO₂, MgO, CaO, pyrochlores of Zr/Ti/Hf/Nb such as SmTi₂O₇, LaZr₂O₇, CeTi₂O₇, CeO₂, La₂O₃, LaHf₂O₇, Gd-doped CeO₂, HfO₂, Al-doped ZnO, In-doped ZnO, Sb-doped ZnO, SnO₂, ZnO and particularly preferably TiO₂ in the form of anatase and/or rutile. In a preferred embodiment according to the invention, these nanoparticles are embedded reactively in the cured base material of the reflector layer. This means that a chemical reaction of the preferably oxidic surface and its hydroxyl groups has taken place with the organically or inorganically cross-linkable functionalities. Preferably, the nanoparticles are bonded chemically to silanol groups or other hydroxyl groups of metal oxides and/or metal organic/hybrid polymeric compounds thereof, in this preferred embodiment, no pores are therefore created between the nanoparticles and the surrounding layer, which would otherwise lead to a reduction of the refractive index of the layer material. In a particular embodiment according to the invention, polysiloxanes may be components of the matrix. These may for example be methyl, phenyl polysiloxanes, which are terminated for example with hydroxyl, glycidyl and/or polyether groups.

The reflector layer may furthermore comprise organic additives, for example dipentaerythritol pentaacrylate, hexanediol diarylate, trimethylolpropane tnacrylate, succinic anhydride as curers. For the production of layers according to the invention, a thickener, for example polydisperse silica, cellulose and/or xanthan, may furthermore be added to the sol-gel carrier substance.

In a particularly preferred embodiment according to the invention, additives such as flow control agents, which may for example come from the substance class of polyether-modified dimethylsiloxanes, are added to the sol-gel carrier substance. The layers may for example be applied by spraying, roll coating, flow coating, doctor blading, pad printing, screen printing etc. Screen printing represents a particularly preferred application method.

The material system of the low-index second reflector layer may be formed according to the prior art. The second reflector layer may for example comprise a colored layer, which preferably comprises acrylates, methacrylates, epoxides, polyvinyl alcohol, polystyrene, water glass, polyurethane, polysiloxane or other conventional carrier substances as its carrier substance. Besides a low refractive index level, these carrier substances are also distinguished by good availability, good dispersibility of the pigments and a multiplicity of possible application methods, for example brushing, rolling, printing, spraying.

In another preferred embodiment, one or both of the reflector layers comprises a film, so that this reflector layer at the same time leads to backside encapsulation of the solar cell. An EVA film (ethylene vinyl acetate), a PVA film (polyvinyl alcohol) or a TPT multilayer laminate film is preferably used, into which the pigments are introduced. A TPT multilayer laminate film generally comprises a polyester film, on both sides of which a PVF (polyvinyl fluoride) film is adhesively bonded. These films are distinguished in particular by high climatic stability and low water permeability. The multilayer reflector can be produced particularly efficiently in this embodiment. If both reflector layers are formed as films, then they may of course also be provided in the form of a multilayer laminate which is laminated onto the back electrode or the absorber layer.

The first reflector layer preferably has a layer thickness of from 5 μm to 60 μm, more preferably from 10 μm to 40 μm, and the second reflector layer a layer thickness of from 10 μm to 1000 μm, preferably from 20 μm to 400 μm. With the comparatively small layer thickness of the first reflector layer, in particular the translucence of the first reflector layer can be ensured. The layer thickness of the second reflector layer depends strongly on whether a white paint with high coverage or a film which simultaneously constitutes the backside encapsulation or a part of the backside encapsulation is used. Whereas sufficient opacity of the reflector can be achieved with white paints having a layer thickness of 100 μm, layer thicknesses of up to 1000 μm are possible for the second reflector layer in the case of the film embodiment.

The invention relates to various designs and types of solar cells. It encompasses solar cells whose the absorber layer comprises amorphous Si(a-Si), microcrystalline Si(μ-Si), recrystallized amorphous, poly- or monocrystalline silicon (c-Si), Cd, Te, In Ga, or S. The invention preferably encompasses thin-film solar cells having an absorber layer thickness of at most 10 μm, the functional layers being arranged on a substrate in a substrate or superstrate arrangement. Nevertheless, the invention also encompasses wafer-based solar cells having an absorber thickness of at least 50 μm.

### BRIEF DESCRIPTION OF THE DRAWING

The objects, features and advantages of the invention are now be illustrated in more detail with the aid of the following description of the preferred embodiment, with reference to the accompanying figures in which:

FIG. 1 is a diagrammatic cross-sectional view through a solar cell having a dielectric reflector according to the prior art;

FIG. 2 is a diagrammatic cross-sectional view through a solar cell having a two-layer dielectric reflector with reference to the example of a thin-film solar cell; and

FIG. 3 is a graphical illustration of the dependence of absorption in % on wavelength for a double reflector layer according to the invention.

### DESCRIPTION OF THE PREFERRED EMBODIMENT

According to FIG. 1, the solar cell 1 according to the prior art comprises a front electrode layer 2, a photovoltaically active absorber layer 3, a back electrode layer 4 and a pigmented dielectric reflector 5 consisting of a single layer. FIG. 1 illustrates possible ray paths for incident radiation, showing that the light back-scattered from the dielectric reflector is strongly refracted by the refraction at the interface with the absorber, and therefore cannot be efficiently absorbed by the absorber.

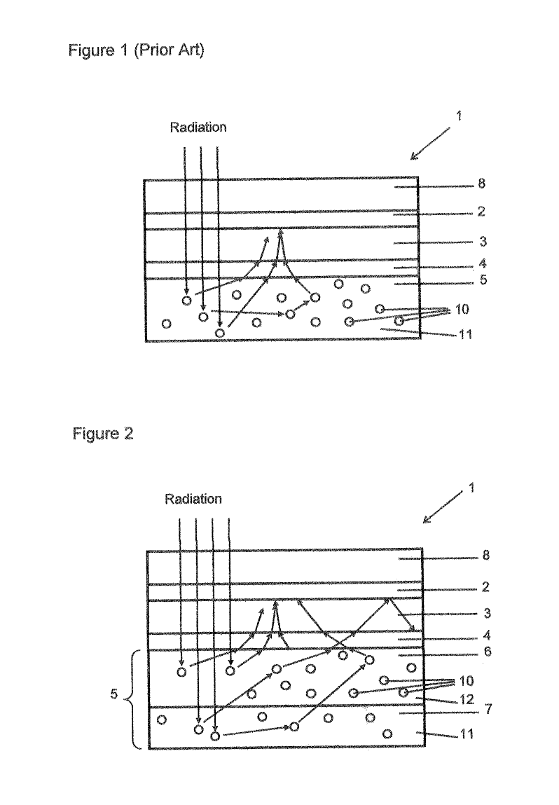

According to FIG. 2, the solar cell 1 according to the invention in a preferred embodiment comprises, preferably in the following order or sequence one above the other, a front electrode layer 2, a photovoltaically active absorber layer 3, a back electrode layer 4, and a pigmented dielectric reflector 5. The pigmented dielectric reflector 5 comprises a first reflector layer 6 and a second reflector layer 7. The first reflector layer 6 comprises pigments 10 in a carrier substance having a high refractive index 12, and the second reflector layer 7 comprises pigments 10 in a carrier substance having a low refractive index 11. FIG. 2 also illustrates possible ray paths for incident radiation, from which it can be seen that the light back-scattered from the dielectric reflector is refracted less strongly and can therefore be absorbed efficiently by the absorber. It also shows that a light trapping effect can take place due to total reflection.

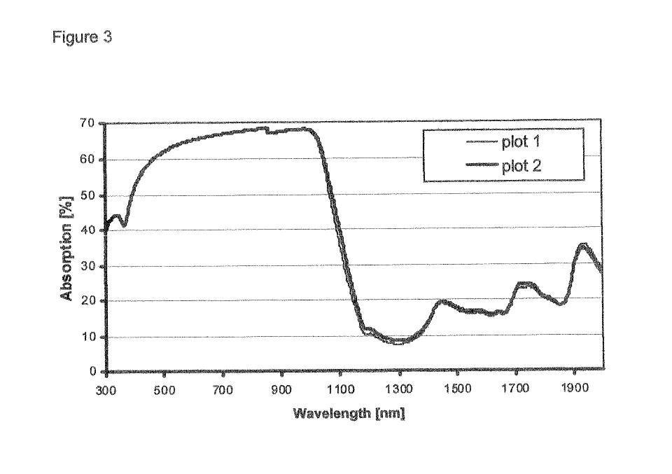

In order to demonstrate the properties according to the invention, a paint formulation for a dielectric first reflector layer having a refractive index of n=1.7 was used. A Si wafer was provided on the one hand according to the prior art with a single low-index dielectric reflector layer, and on the other hand with the double reflector layer according to the invention. The absorptions of the two layer systems were subsequently determined, as represented in FIG. 3. For the double reflector layer according to the invention, which is denoted by plot 2 in FIG. 3, compared with the single reflector layer which is denoted by plot 1 in FIG. 3, a shift of the absorbance edge into the long-wavelength spectral range is observed, which confirms an improvement of the light trapping.

The production of the high-index reflector layer is described in the following paragraphs.

In a first step, a respective base paint is prepared, which is a precursor of the carrier substance of the corresponding reflector layer. Possible formulations of the carrier substance of the high-index first reflector layer are of three types:
1) UV-curable, organically and inorganically cross-linked,
2) thermally curable, organically and inorganically cross-linked, and
3) thermally curable, inorganically cross-linked, screen-printable.

A first base paint, which is UV-curable and organically and inorganically cross-linked, can be obtained as follows: methacryloxypropyltriethoxysilane (MPTES), tetraethoxysilane (TEOS) and methyltriethoxysilane (MTEOS) are placed in a vessel. In this exemplary embodiment, for example, about 0.75 mol of MPTES, about 0.2 mol of TEOS and about 0.005 mol of MTEOS are used. 3.44 g of para-toluene sulfonic acid in 23 g of distilled water are subsequently added slowly to this solution while cooling and stirring. After 5 min of stirring, 900 g of a dispersion of 20 wt. % anatase nanoparticles with a crystallite size of from 10 to 15 nm in n-butanol are added. This solution is combined with a solution of zirconium propylate and methacrylic acid. For example, 0.75 mol of MPTES, 0.02 mol of TEOS and 0.05 mol of MTEOS plus a solution of 0.3 mol zirconium propylate and 0.3 mol of methacrylic acid may be used. After the end of the hydrolysis, which may take a period of about 24 hours, the hybrid polymer sol obtained with reactively embedded, finely dispersed, non-agglomerated nanoparticles is diluted with methoxypropanol. A photoinitiator is added to the paint formulation. For example, 1 wt. % of the photoinitiator, 1-hydroxycyclohexyl phenyl ketone, which is available under the brand name IRGACURE® 184, is added, in relation to or based on the viscous hybrid polymer.

A second base paint, which is thermally curable and organically and inorganically cross-linked, can be obtained as follows: glycidoxypropyltriethoxysilane (GPTES), TEOS and MTEOS are placed in a vessel. For example, about 0.6 mol of GPTES, 0.2 mol of TEOS and 0.2 mol of MTEOS are used. This solution is combined with a solution of aluminium secondary butyl acrylate and ethyl acetate, for example 0.1 mol each. An acidic dispersion of an aqueous nanoparticulate of TiO₂, to which methanol and p-toluene sulfonic acid have been added, is subsequently introduced slowly into the aforesaid solution while cooling and stirring. For example, about 28 g of a TiO₂ dispersion having 18 wt. % of anatase with a crystallite size of from 7 to 12 nm, to which about 60 g of methanol and 3.44 g of p-toluene sulfonic acid have been added, may be introduced. After 5 min of stirring, 1000 g of a dispersion of 20 wt. % anatase nanoparticles with a crystallite size of 10 to 15 nm in n-butanol are added. After the end of the hydrolysis, which may take a period of about 24 hours, the solvent (for example methanol/ethanol) is removed using a rotary evaporator. The hybrid polymer sol obtained with reactively embedded, finely dispersed, non-agglomerated nanoparticles is diluted with methoxypropanol. Then 0.05 mol of succinic anhydride is added and a thermostarter is added to the coating formulation. For example, 2 wt. % of N-methylimidazole may be added as the thermostarter.

A third base paint, which is thermally curable, inorganically cross-linked and screen-printable, can be obtained as follows: TEOS and MTEOS are placed in a vessel. In this exemplary embodiment for example about 0.2 mol of TEOS and about 0.8 mol of MTEOS are used. An aqueous nanoparticulate dispersion of TiO₂ particles, to which methanol and p-toluene sulfonic acid have been added, is subsequently slowly introduced into this solution while cooling and stirring. For example, about 28 g of a TiO₂ dispersion having 18 wt. % of anatase with a crystallite size of 7 to 12 nm, supplemented with about 60 g of methanol and 3.44 g of p-toluene sulfonic acid, may be added. After 5 min of stirring, 950 g of a dispersion of 20 wt. % anatase nanoparticles with a crystallite size of from 10 to 15 nm in n-butanol are added. After the end of the hydrolysis, which may take a period of about 24 hours, the hybrid polymer sol obtained with reactively embedded, finely dispersed, non-agglomerated nanoparticles is diluted with diethylene glycol monoethyl ether and the highly volatile solvent is removed at 100 mbar and 40° C.

In a second step, pigments can be added to the base paint. Depending on the desired coverage, usually from 30 to 60 wt. % of white pigments with a size of 100 nm to 5 μm are added and dispersed using a dispersing device. The particles used may in particular be:
50 wt. % rutile with a particle size of from 350 nm to 500 nm,
60 wt. % anatase with an average particle size of 125 nm, or
45 wt. % ZnS with an average particle size of 1000 nm.

In a third step, the paint containing the pigment is applied by the screen printing method and thermally and/or photochemically cured.

### Parts List

1 Solar cell
2 Front electrode layer
3 Absorber layer
4 Back electrode layer
5 Dielectric reflector
6 First reflector layer
7 Second reflector layer
8 Substrate
10 Pigments
11 Carrier substance with low refractive index
12 Carrier substance high low refractive index

While the invention has been illustrated and described as embodied in a solar cell with an improved pigmented dielectric reflector, it is not intended to be limited to the details shown, since various modifications and changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention.

What is claimed is new and is set forth in the following appended claims:

1. A solar cell (1) comprising a plurality of functional layers, said functional layers including a front electrode layer (2), a photovoltaically active absorber layer (3), a back electrode layer (4) and a pigmented dielectric reflector (5);
wherein the pigmented dielectric reflector (5) has a refractive index profile perpendicular to the functional layers with at least two different refractive indices, said refractive index profile having a refractive index n₁ at a distance d₁ from the absorber layer and a refractive index n₂ at a distance d₂ from the absorber layer, said distance d₂ being greater than said distance d₁; and
wherein said refractive index n₁ at said distance d₁ is greater than said refractive index refractive index n₂ at said distance d₂ from the absorber layer.

2. The solar cell according to claim 1, wherein the back electrode layer (4) comprises a transparent conductive oxide (TCO) layer having a refractive index n_{R}, and wherein the dielectric reflector (5) has a maximum refractive index corresponding at most to the refractive index n_{R} of the transparent conductive oxide layer.

3. The solar cell according to claim 1, wherein the back electrode layer (4) comprises a heavily doped surface layer that is part of the absorber layer (3).

4. The solar cell according to claim 1, wherein the different refractive indices of the refractive index profile of the pigmented dielectric reflector increase in a plurality of individual steps or continuously in a direction toward the absorber layer.

5. The solar cell according to claim 1, wherein the pigmented dielectric reflector (5) comprises a first reflector layer (6) and a second reflector layer (7), the first reflector layer (6) is closer to the absorber layer (3) than the second reflector layer (7), the first reflector layer (6) comprises a first carrier substance with a refractive index n_{T,1} and pigments (10) embedded therein and the second reflector layer (7) comprises a second carrier substance with a refractive index n_{T,2} and pigments embedded therein.

6. The solar cell according to claim 5, wherein said pigments have a particle size in a range of 0.1 μm to 5 μm and comprise at least one ingredient selected from the group consisting of rutile, anatase, BaSO₄ and ZnS.

7. The solar cell according to claim 6, wherein said particle size is from 0.1 μm to 1 μm.

8. The solar cell according to claim 6, wherein the first reflector layer and the second reflector layer each contain from 10 vol % to 90 vol % of said pigments.

9. The solar cell according to claim 6, wherein the first reflector layer and the second reflector layer each contain from 30 vol % to 60 vol % of said pigments.

10. The solar cell according to claim 5, wherein the first reflector layer (6) has a translucence of from 10% to 90%.

11. The solar cell according to claim 10, wherein the translucence is from 25% to 75%.

12. The solar cell according to claim 5, wherein the refractive index n_{T,1} of the first carrier substance of the first reflector layer (6) is at least 1.6.

13. The solar cell according to claim 5, wherein the refractive index n_{T,1} of the first carrier substance of the first reflector layer (6) is at least 1.8.

14. The solar cell according to claim 5, wherein the refractive index n_{T,2} of the second carrier substance of the second reflector layer (7) is less than 1.6.

15. The solar cell according to claim 5, wherein the refractive index n_{T,2} of the second carrier substance of the second reflector layer (7) is less than 1.5.

16. The solar cell according to claim 5, wherein the refractive index n_{T,1} of the first carrier substance is at least 0.1 greater than the refractive index n_{T,2} of the second carrier substance.

17. The solar cell according to claim 5, wherein the refractive index n_{T,1} of the first carrier substance is at least 0.3 greater than the refractive index n_{T,2} of the second carrier substance.

18. The solar cell according to claim 5, wherein the first carrier substance of the first reflector layer comprises an organic and/or hybrid polymeric and/or polysiloxane-based base material.

19. The solar cell according to claim 5, wherein the first carrier substance of the first reflector layer comprises an organic/inorganic hybrid polymeric base material.

20. The solar cell according to claim 5, wherein the first carrier substance of the first reflector layer (6) is made by a sol-gel method from hydrolyzable and polycondensable silicon or silicon-organic compounds and optionally hydrolyzable and polycondensable titanium, zirconium, aluminium, zinc, magnesium, calcium, cerium, samarium, gadolinium, lanthanum, boron, yttrium and/or tin compounds.

21. The solar cell according to claim 20, wherein the silicon or silicon-organic compounds are photochemically or thermally polymerizable.

22. The solar cell according to claim 5, wherein the first carrier substance of the first reflector layer (6) comprises at least 10 vol % of high-index nanoparticles with a refractive index of at least 2.0 and said high-index nanoparticles have an average particle size of 2 nm to 50 nm, so that the refractive index of the first carrier substance is increased.

23. The solar cell according to claim 5, wherein the first carrier substance of the first reflector layer (6) contains at least 20 vol % of high-index nanoparticles with a refractive index of at least 2.0 and said high-index nanoparticles have an average particle size of 4 nm to 30 nm, so that the refractive index of the first carrier substance is increased.

24. The solar cell according to claim 23, wherein the high-index nanoparticles comprise one or more oxides selected from the group consisting of ZrO₂, Y₂O₃ stabilized ZrO₂, CaO-stabilized ZrO₂, MgO-stabilized ZrO₂, CeO₂-stabilized ZrO₂, MgO, CaO, pyrochlores of Zr/Ti/Hf/Nb, SmTi₂O₇, LaZr₂O₇, CeTi₂O₇, CeO₂, La₂O₃, LaHf₂O₇, Gd-doped CeO₂, HfO₂, Al-doped ZnO, In-doped ZnO, Sb-doped ZnO, SnO₂ and ZnO.

25. The solar cell according to claim 23, wherein the high-index nanoparticles comprise TiO₂ in the form of anatase and/or rutile.

26. The solar cell according to claim 5, wherein the second reflector layer (7) comprises a colored layer, said colored layer has another carrier substance that comprises acrylates, methacrylates, epoxides, polyvinyl alcohol, polystyrene, water glass, polyurethane or polysiloxane.

27. The solar cell according to claim 5, wherein at least one of the first reflector layer (6) and the second reflector layer (7) is a film and said film is an ethylene-vinyl acetate film (EVA), a polyvinyl alcohol film (PVA), or a TPT multilayer laminate film.

28. The solar cell according to claim 5, wherein the first reflector layer (6) has a layer thickness of 5 μm to 60 μm and the second reflector layer (7) has a layer thickness of 10 μm to 1000 μm.

29. The solar cell according to claim 5, wherein the first reflector layer (6) has a layer thickness of 10 μm to 40 μm and the second reflector layer (7) has a layer thickness of 20 μm to 400 μm.

30. The solar cell according to claim 1, wherein the absorber layer comprises amorphous Si(a-Si), microcrystalline Si(μ-Si), recrystallized amorphous, poly- or monocrystalline silicon (c-Si), Cd, Te, In, Ga, or S.

31. The solar cell according to claim 1, which is a thin-film solar cell, and wherein the functional layers are arranged on a substrate, in a substrate or in a superstrate arrangement.

32. The solar cell according to claim 1, which is a wafer-based solar cell having an absorber layer thickness of at least 50 μm.
